(19) United States
(12) Patent Application Publication
(10) Pub. No.: US 2009/0168829 A1
(43) Pub. Date: Jul. 2, 2009

(54) VERTICAL-CAVITY SURFACE-EMITTING LASER

(75) Inventors: Tomofumi KISE, Tokyo (JP); Noriyuki Yokouchi, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: The Furukawa Electric Co., Ltd., Chiyoda-ku (JP)

(21) Appl. No.: 12/342,351

(22) Filed: Dec. 23, 2008

Related U.S. Application Data
(63) Continuation of application No. PCT/JP2007/066986, filed on Aug. 31, 2007.

(30) Foreign Application Priority Data
Aug. 31, 2006 (JP) 2006-235155

(51) Int. Cl. H01S 5/183

(52) U.S. Cl. 372/50.124

(57) ABSTRACT

A vertical-cavity surface-emitting laser (VCSEL) includes a substrate, and a layer structure including a first reflector, an active layer, and a second reflector, which are consecutively layered on the substrate, and a plurality of holes arranged in a two-dimensional structure periodically within a layer plane except for a specified area of the layer structure, wherein a pair of holes sandwiching therebetween the specific area and opposing each other have a dimension or shape different from the dimension or shape of others of the holes.

This application is a continuation application from a PCT application No. PCT/JP2007/066986 filed on Aug. 31, 2007, the disclosure of which is incorporated herein in its entirety by reference.

### TECHNICAL FIELD

The present invention relates to a vertical-cavity surface-emitting laser and, more particularly, to a vertical-cavity surface-emitting laser which is capable of lasing at a stable polarization mode.

### BACKGROUND

The vertical-cavity surface-emitting laser (referred to simply as VCSEL, hereinafter) is such that the lasing direction of light is vertical to the substrate surface, as the appellation shows, and attracts a significant attention as a light source for communication, or a variety of application devices such as a sensor application.

The reason for attracting the attention as described above is based on the advantages that the VCSEL has over the conventional edge-emitting laser, such as advantages that the VCSEL is easily formed to have a two-dimensional arrangement of the devices, that a wafer-level test is possible due to absence of necessity of the cleavage for providing a mirror of the cavity, and that the power dissipation thereof is smaller because of lasing at an extremely lower threshold due to a drastically smaller volume of the active layer.

Generally, there are three modes in the lasing of semiconductor lasers: longitudinal mode, transverse mode and polarization mode.

As for the longitudinal mode, since the VCSEL has an extremely smaller cavity length, the VCSEL achieves a fundamental longitudinal mode lasing with ease.

As for the transverse mode, since the VCSEL does not have a control mechanism for the transverse mode, the VCSEL is likely to lase in a plurality of higher order modes. If a laser beam lasing in the plurality of higher order modes is used in an optical transmission, there arises a considerable degradation which is proportional to the transmission distance, especially during a high-speed modulation. In the VCSEL, the simplest method for obtaining the fundamental transverse mode lasing is to reduce the active area so that lasing only in the fundamental transverse mode is achieved. However, in addition to the difficulty of forming a narrow active area with a higher reproducibility, there inevitably arises a problem in that the smaller active area reduces the output power and increases the device resistance as well as the applied voltage.

Thus, in the VCSEL, as a measure for achieving the fundamental transverse mode lasing in a larger area, there is a proposed structure described in a literature “IEEE Journal of Selected Topics in Quantum Electronics, Vol. 9, No. 5, pp. 1439-1445, September/October 2003” (non-patent publication 1). FIG. 15 is a partially-fragmented, perspective view of the VCSEL disclosed in the non-patent publication 1, and FIG. 16 is the top plan view thereof. In this VCSEL, a layer structure 11 including a lower reflector 2 configured by a semiconductor distributed multi-layer film, an active layer 3, and a upper reflector 4 configured by a semiconductor distributed multi-layer film and deposited on the active layer 3, is formed on a substrate 1, and a plurality of circular holes 8 are formed and arranged in a periodic two-dimensional arrangement within the layer plane. The two-dimensional circular-hole arrangement within the layer plane includes a point defect area 9 including no circular hole in the central part thereof, and the circular holes 8 are formed in the thickness direction from the top surface to an intermediate portion of the upper reflector 4.

An upper electrode 5 is formed in the peripheral area outside the circular-hole arrangement, and a lower electrode 6 is formed on the bottom surface of the substrate 1. A layer located in the vicinity of the topmost layer of the lower reflector 2, i.e., the vicinity of the active layer 3 is configured by a p-type AlAs layer 7, for example, which is selectively oxidized in the outer periphery thereof to form an insulation area 7a configured by Al₂O₃, and acts as a current confinement structure for the active layer 3.

In the VCSEL 10, the arrangement of the plurality of circular holes as described above allows the refractive index sensed by the light in the area where the circular holes 8 are arranged to be lower as compared with the point defect area (central part) 9 without the circular holes. As a result, the portion in which the circular holes are arranged acts as a clad for the point defect area 9 in the central part without the circular hole. Injection of current into the VCSEL through the top electrode 5 and bottom electrode 6 causes a lasing within the active layer 3. In this case, based on the minor difference in the refractive index of the two-dimensional arrangement of the circular holes between the central point defect area 9 and the peripheral portion in which the circular holes are arranged, lasing in the fundamental transverse mode is achieved in a larger area including the point defect area 9. (A VCSEL wherein the refractive-index difference is formed by the arrangement of circular holes to control the transverse mode, as described above, is referred to as “photonic-crystal VCSEL” sometimes.) In this VCSEL, lasing in the fundamental transverse mode can be achieved in the larger area, to thereby realize a lower-voltage operation due to a higher output power and a lower resistance.

The present inventors performed the following investigations as to the VCSEL device. Although a linearly-polarized light can be generally obtained as the polarization mode of the VCSEL, there arises a problem. Specifically, the problem is that the device structure itself of the VCSEL has a six-fold rotational symmetry with respect to the central axis “C” of the point defect area 9 (the electromagnetic field distribution within a half plane including the central axis C is substantially equivalent to that after a rotation of 60 degrees), as shown by numerals I-VI in FIG. 16, and the gain and loss of the possible polarization modes determined by this rotational symmetry of the circular-hole arrangement pattern are equivalent thereamong, whereby there arises a competition among these polarization modes. As a result, the direction of polarization is not stable because a subtle change in the external conditions such as ambient temperature and drive current will cause a frequent switching between the polarization modes. This instability of the polarization mode may cause a factor of excessive noise, and restriction of the transmission band due to the polarization mode dispersion of the transmission medium.

In the above view points, there is a known process in which the VCSEL is formed on an inclined substrate as a technique for stabilizing the polarization mode in a typical VCSEL, i.e., not in a photonic-crystal VCSEL. This process takes advantage of the gain depending on the crystal orientation, and forms an active layer on a crystal plane of a higher-index-orientation, such as on (311)-A plane or (311)-B plane, in order to increase the gain of the polarization mode of a specific orientation.

However, there is a problem in that it is difficult to achieve a superior-quality epitaxial growth therein and thus to obtain a higher output power, as compared with the case of deposition of an active layer on an ordinary (100) plane. In addition, if a VCSEL including a selectively-oxidized layer as the current confinement structure as depicted in FIG. 15 is deposited on the inclined substrate, the difference in the oxidizing rate depending on the crystal orientation (anisotropic oxidation) causes deformation in the shape of oxidized portion, and accordingly in the shape of the active area, thereby incurring the problem of difficulty in the control of beam shape.

There are some known structures, other than the above described structure, such as an asymmetric shape introduced into the mesa shape of a device, and a diffraction grating configured by a metal or dielectric and introduced into a reflector configured by a semiconductor distributed multilayer film (patent publication 1). However, any of these structures incurs a complicated device processing and an insufficient controllability of the polarization.

Non-Patent Publication 1: IEEE Journal of Selected Topics in Quantum Electronics, Vol. 9, No. 5, pp. 1439-1445, September/October 2003

Patent Publication 1: JP-1999-54838A

### SUMMARY OF THE INVENTION

It is an object of the present invention to solve the above-described problem involved in the VCSELs, and to provide a VCSEL which is capable of lasing with the fundamental transverse mode in a larger area, has an improved stability of the polarization mode, and is manufactured with ease.

The present invention provides, in a first aspect thereof, a surface-emitting laser (VCSEL) including: a substrate; a layer structure including a first reflector, an active layer, and a second reflector which are consecutively layered on said substrate; and a plurality of holes formed in a layered direction and arranged in a periodic two-dimensional arrangement within a layer plane of said layer structure except for a specific area in said layer plane, wherein a pair of holes sandwiching therebetween said specific area to oppose each other have a dimension or shape different from a dimension or shape of others of said holes.

Here, the specific area is a point defect area including therein no holes that are arranged in a periodic two-dimensional arrangement.

The present invention provides, in a second aspect thereof, a VCSEL including: a substrate; a layer structure including a first reflector, an active layer, and a second reflector which are consecutively layered on said substrate; and a plurality of holes formed in a layered direction and arranged in a periodic two-dimensional arrangement within a layer plane of said layer structure except for a specific area in said layer plane, wherein some of said holes having a center located on a straight line passing through a center of said specific area within said layer plane have a dimension or shape different from a dimension or shape of others of said holes.

The present invention provides, in a third aspect thereof, a VCSEL including: a substrate; a layer structure including a first reflector, an active layer, and a second reflector which are consecutively layered on said substrate; and a plurality of holes formed in a layered direction and arranged in a periodic two-dimensional arrangement within a layer plane of said layer structure except for a specific area in said layer plane, wherein some of said holes, the angle defined between a line segment connecting together a center of which and a center of the specific area and a half straight line extending from the center of the specific area within the layer plane resides within a specific range, have a dimension or shape different from a dimension or shape of others of said air holes.

It is preferable in the third aspect that if the plurality of holes are arranged in a triangular-lattice structure within the layer plane, the some of the holes, the angle defined between the line segment connecting together the center of which and the center of the specific area and the half straight line resides within a range between 60 degrees and 120 degrees, inclusive of both angles, have a dimension or shape different from a dimension or shape of the others of the holes.

It is also preferable in the third aspect that if the plurality of holes are arranged in a square-lattice structure within the layer plane, some of the holes, the angle defined between the line segment connecting together the center of which and the center of the specific area and the half straight line resides within a range between 45 degrees and 135 degrees, inclusive of both angles, have a dimension or shape different from a dimension or shape of the others of the holes.

The present invention provides, in a fourth aspect thereof, a VCSEL including: a substrate; a layer structure including a first reflector, an active layer, and a second reflector which are consecutively layered on the substrate; and a plurality of holes formed in a layered direction and arranged in a periodic two-dimensional arrangement within a layer plane of the layer structure except for a specific area in the layer plane, wherein a pair of holes among the holes, which sandwich therebetween the specific area to oppose each other, are filled with a loss medium that incurs a loss to a laser light.

The present invention provides, in a fifth aspect of thereof, a VCSEL including: a substrate; a layer structure including a first reflector, an active layer, and a second reflector which are consecutively layered on the substrate; and a plurality of holes formed in a layered direction and arranged in a periodic two-dimensional arrangement within a layer plane of the layer structure except for a specific area in the layer plane, wherein some of the holes having a center located on a straight line passing through a center of the specific area within the layer plane are filled with a loss medium that incurs a loss to a laser light.

The present invention provides, in a sixth aspect thereof, a VCSEL including: a substrate; a layer structure including a first reflector, an active layer, and a second reflector which are consecutively layered on the substrate; and a plurality of holes formed in a layered direction and arranged periodically in a two-dimensional arrangement within a layer plane of the layer structure except for a specific area in the layer plane, wherein some of the holes, the angle defined between a line segment connecting together a center of which and a center of the specific area and a half straight line extending from the center of the specific area within the layer plane resides within a specific range, are filled with a loss medium that incurs a loss to a lasing beam.

It is preferable in the sixth aspect that if the plurality of holes are arranged in a triangular-lattice structure within the layer plane, some of the holes, the angle defined between the line segment connecting together the center of which and the center of the specific area and the half straight line resides within a range between 60 degrees and 120 degrees, inclusive of both angles, are filled with a loss medium that incurs a loss to a laser light.

It is preferable in the sixth aspect that if the plurality of holes are arranged in a square-lattice structure within the layer plane, some of the holes, the angle defined between the line segment connecting together the center of which and the center of the specific area and the half straight line resides within a range between 45 degrees and 135 degrees, inclusive of both angles, are filled with a loss medium that incurs a loss to a laser light.

It is preferable in the fourth through sixth aspects that the loss medium that incurs a loss to the laser light includes polyimide.

It is preferable in the first through sixth aspects that the plurality of holes be circular holes. It is also preferable in the first through sixth aspects that if the plurality of holes are square circular holes, one of the square holes has two opposing sides parallel to two opposing sides of the others of the holes, that is, all the square holes be aligned in the orientation thereof.

In the first through sixth aspects of the present invention, a rotational symmetry of the arrangement pattern of the holes with respect to the central axis configured by an axis passing through a center of the specific area, i.e., a point defect area within the arrangement pattern of the plurality of holes arranged in a periodic two-dimensional arrangement, in the layered direction of the layer structure defines a plurality of possible polarization modes, one of which has a loss smaller than a loss of others of the polarization modes. Thus, only the one of the polarization modes selectively lases, and competition between the polarization modes is prevented to thereby stabilize the lasing polarization mode. Accordingly, occurring of noise due to switching between the polarization modes is suppressed, to thereby prevent the polarization mode dispersion from restricting the transmission band.

The above and other objects, features and advantages of the present invention will be more apparent from the following description, referring to the accompanying drawings.

### BRIEF DESCRIPTION OF THE DRAWINGS

FIG. 1 is a top plan view showing a VCSEL according to a first embodiment of the present invention.

FIG. 2 is a sectional perspective view showing the VCSEL of FIG. 1.

FIG. 3 is a top plan view exemplifying a VCSEL according to a modification of FIG. 1.

FIG. 4 is a top plan view showing a VCSEL according to a second embodiment of the present invention.

FIG. 5 is a sectional perspective view showing the VCSEL of FIG. 4.

FIG. 6 is a top plan view showing a VCSEL according to a third embodiment of the present invention.

FIG. 7 is sectional perspective view showing the VCSEL of FIG. 6.

FIG. 8 is a top plan view exemplifying a modification of the VCSEL of FIG. 6.

FIG. 9 is a top plan view showing a VCSEL according to a fourth embodiment of the present invention.

FIG. 10 is a sectional perspective view showing the VCSEL of FIG. 9.

FIG. 11 is a top plan view showing a VCSEL according to a fifth embodiment of the present invention.

FIG. 12 is a sectional perspective view showing the VCSEL of FIG. 11.

FIG. 13 is a top plan view showing a VCSEL according to a sixth embodiment of the present invention.

FIG. 14 is a top plan view exemplifying a modification of the VCSEL of FIG. 13.

FIG. 15 is a partly-fragmented, perspective view showing a conventional VCSEL.

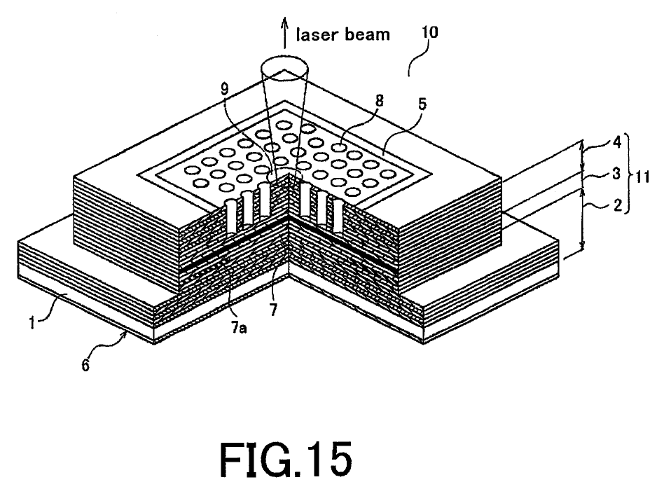

FIG. 16 is a top plan view of the VCSEL of FIG. 15.

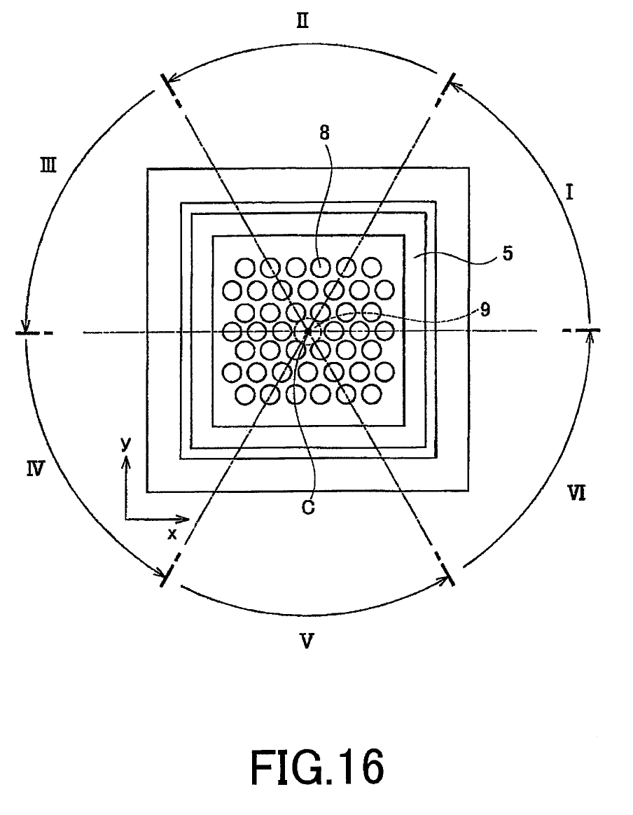

### EMBODIMENTS OF THE INVENTION

### First Embodiment

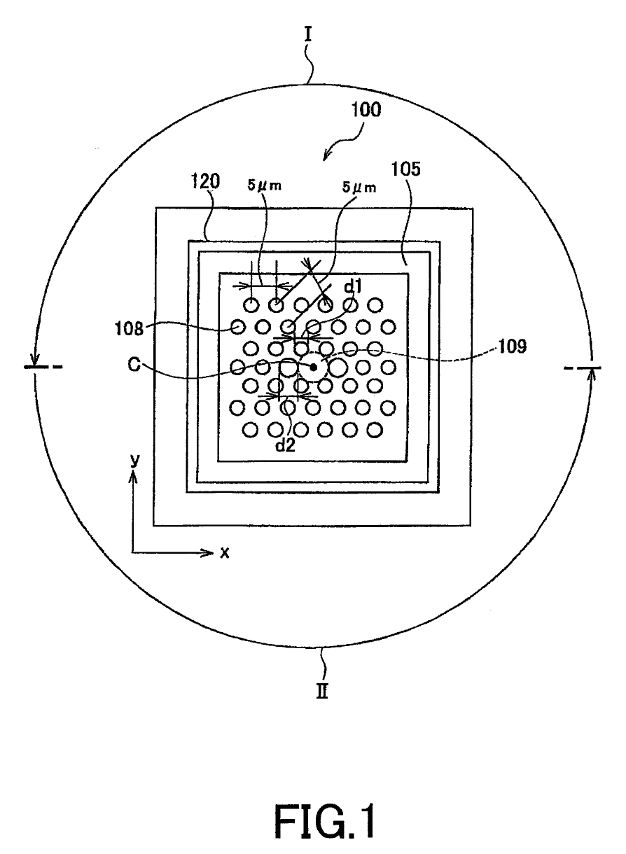

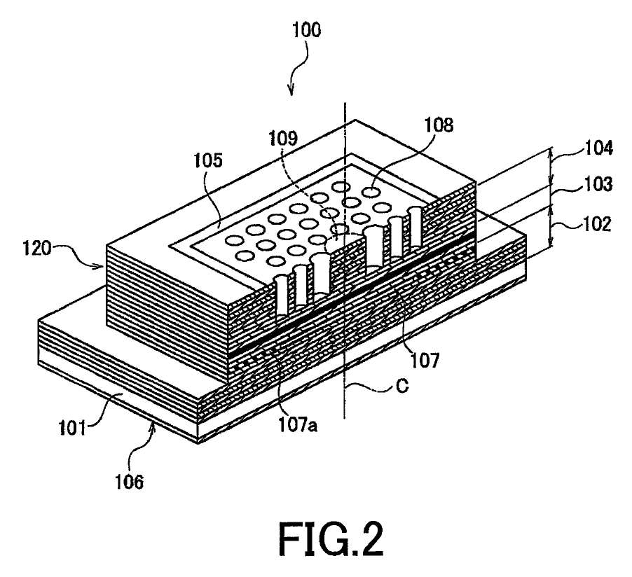

Hereinafter, a first embodiment of the present invention will be described with reference to drawings. FIG. 1 is a top plan view of a VCSEL according to the first embodiment of the present invention, and FIG. 2 is a sectional perspective view thereof.

The VCSEL 100 according to the first embodiment of the present invention is a photonic-crystal VCSEL for use in an emission wavelength of 850 nm, wherein a lower reflector 102, an active layer 103 including a lower cladding layer configured by Al_{0.3}Ga_{0.7}As, a multiple-quantum well configured by four pairs of GaAs/Al_{0.2}Ga_{0.8}As and an upper cladding layer configured by Al_{0.3}Ga_{0.7}As, and an upper reflector 104 are consecutively layered on a (100) surface of a p-type GaAs substrate 101, and an n-type GaAs contact layer is formed on the surface of the topmost layer of the upper reflector 104, to configure the overall layer structure. In order to form a current confinement structure, a p-type AlAs layer 107, for example, is inserted in the above layer structure.

The lower reflector 102 includes a semiconductor multilayer film configured by 20 pairs of alternately deposited p-type AlAs and p-type GaAs layers, each of the layers having a thickness of λ/4n (where n is a refractive index, and λ is an operating wavelength), and another semiconductor multilayer film configured by 15 pairs of alternately deposited p-type Al_{0.9}Ga_{0.1}As and p-type Al_{0.2}Ga_{0.8}As, each of the layers having a thickness of λ/4n (where n is a refractive index and λ is an operating wavelength). The upper reflector 104 includes a semiconductor multilayer film configured by 25 pairs of alternately deposited n-type Al_{0.9}Ga_{0.1}As and n-type Al_{0.2}Ga_{0.8}As, each of the layers having a thickness of λ/4n.

A portion of the above layer structure as viewed from the top thereof to at least the top surface of the lower reflector 102 is removed by etching for the peripheral part thereof, to configure a columnar layer structure 120. The p-type AlAs layer 107 deposited in the vicinity of the active layer 103 in the above columnar layer structure 120 is oxidized in an area thereof from a portion exposed from the side surface of the columnar layer structure 120 toward the center thereof, to configure a insulation area 107a made of Al₂O₃. This insulation area 107a functions as a current confinement structure with respect to the current injected into the active layer 103.

As shown in FIG. 1, a plurality of circular holes 108 are formed and arranged in the columnar structure 120, to form a two-dimensional equilateral-triangular-lattice structure within the layer plane, by using an electron beam exposure or photolithography and a dry etching. This circular-hole arrangement includes a point defect area 109 in the central area thereof, the point defect area including therein no circular hole. The plurality of circular holes 108 has an arrangement period of 5 micrometers (in the distance between centers thereof), and are formed to a depth corresponding to 17 pairs of the upper reflector 104 from the top surface of the columnar layer structure 120. Due to such a circular-hole arrangement, the average refractive index of the portion in which the circular holes 108 are formed is lower than the average refractive index of the point defect area 109 without the circular hole, whereby the portion in which the circular holes 108 are formed functions as a clad to the light propagating in the point defect area 109. The arrangement period, hole diameter and depth, etc. of the circular holes 108 are adjusted as desired so that the fundamental transverse mode lasing may be obtained within the layer plane depending on the average refractive index difference between the portion in which the circular holes 108 are formed and the point defect area 109 without the circular hole.

An upper electrode 105 made of AuGeNi/Au, for example, is formed in the peripheral area of the portion in which the circular holes are arranged in the columnar layer structure 12. A lower electrode 106 made of Ti/Pt/Au is formed on the bottom surface of the p-type GaAs substrate 101.

In the first embodiment, as shown in FIG. 1, a pair of circular holes disposed in the vicinity of the center and sandwiching therebetween the central point defect area 109 to oppose each other have a diameter d₂ which is larger than the diameter d₁ of the other circular holes. In the present embodiment, the diameters d₁ and d₂ of the circular holes are 2 micrometers and 3 micrometers, respectively, for example. This arrangement of circular holes having different diameters allows the pattern of circular holes to have a two-fold rotational symmetry with respect to the central axis “C” passing through the center of the point defect area 109 perpendicularly to the layer plane, as shown by numerals I and II in FIG. 1. More specifically, the electro-magnetic-field distribution of the light of the VCSEL in a half plane including the central axis thereof is equivalent to that in the case of rotating the same by 180 degrees around the central axis as a rotational center.

The polarization modes of this VCSEL 100 include two possible polarization modes corresponding to the symmetry of the above circular-hole arrangement pattern; however, the polarization modes are subjected to different losses. In the present embodiment, since the loss against the polarization mode having an electric field parallel to the x-direction shown in FIG. 1 (parallel to the direction of connecting together the centers of larger-diameter circular holes) is larger than the loss against the polarization mode parallel to the y-direction (direction perpendicular to the x-direction within the layer plane), the lasing in the polarization mode parallel to the y-direction becomes dominant.

Accordingly, upon injecting current through the electrodes 105, 106, only the lasing in the polarization mode of y-direction having a lower loss selectively occurs out of the two polarization modes. For this reason, a stable lasing is obtained in which a switching between polarization modes due to fluctuation of the environmental temperature or drive current scarcely occurs.

Calculation was conducted using the above parameters with respect to the first embodiment, whereby it was confirmed that lasing in the polarization mode of the y-direction dominates, and that the ratio (orthogonal polarization suppression ratio) of the lasing intensity of polarization mode in the y-direction to that in the x-direction is 30 dB or more. It was assured that a fundamental transverse mode lasing is obtained for the transverse mode.

In the first embodiment, as shown in FIG. 1, the diameter of d₂ of circular holes in one of the pairs of circular holes having a smallest distance therebetween among the pairs of circular holes opposing each other in each pair with an intervention of the central point defect area 109 is determined to be larger than the diameter d₁ of the others of the pairs. The present example is advantages, due to the fact that the pair of circular holes having a smallest distance with respect to the point defect area 109 have a diameter different from the diameter of the other circular holes, in that the different diameter of the circular holes provides the effect thereof more effectively to the electric field of the laser light existing in the point defect area 109. In addition, since circular holes having the same diameters are arranged with a two-dimensional uniformity in the peripheral area excepting the vicinity of the central point defect area 109, the influence by a disturbance onto the distribution of refractive index within the layer plane can be reduced. More specifically, the influence on the shape of the laser light can be reduced.

It should be noted however that a pair of circular holes other than the circular holes having the smallest distance with respect to the point defect area 109 may have a different diameter if desired, in order to differentiate the loss between the polarization modes.

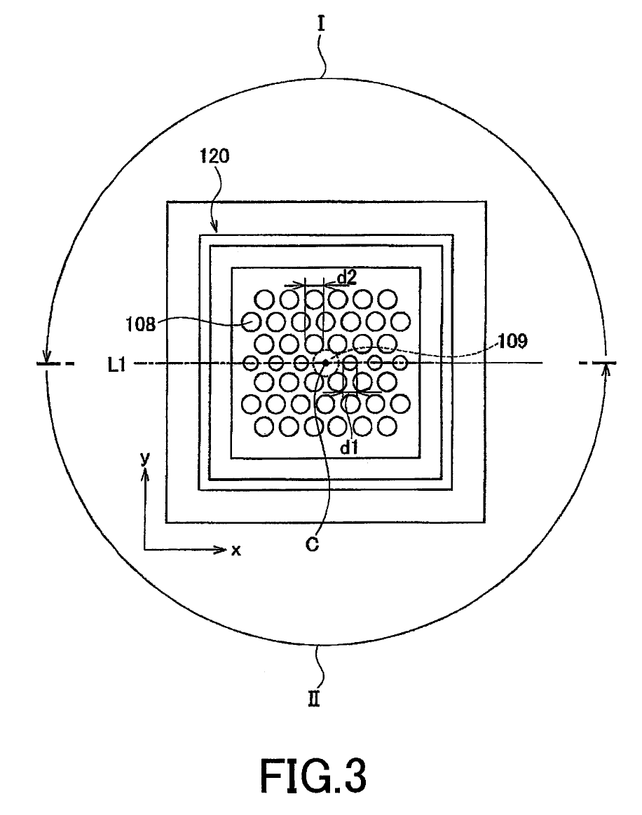

Further, as shown in FIG. 3, circular holes having a center arranged on a straight line, which extends through the center of the point defect area 109 and parallel to the layer plane, may have a diameter different from the diameter of the other circular holes. In the exemplified modification shown in FIG. 3, the diameter d₁ of the circular holes having a center on the straight line L1, which extends through the center of point defect area 109 parallel to the x-axis, is made smaller than the diameter d₂ of the other circular holes having a center not located on the straight line L1. For this reason, the loss for the polarization mode in the x-axis direction, shown in FIG. 3, is smaller than the loss for the polarization mode in the y-axis direction. Therefore, a selective lasing occurs for the polarization mode in the x-axis direction, whereby switching between the polarization modes can be prevented. Thus, the configuration that all the circular holes having a center on the straight line L1 passing through the center of the point defect area 109 within the layer plane have a diameter different from the diameter of the other circular holes having a center not located on the straight line L1 further intensifies the degree of rotational asymmetry with respect to the central axis C, thereby increasing the stability of the lasing polarization mode.

Although, in the above description, the circular holes located on a specific position among the plurality of circular holes have a diameter different from the diameter of the other circular holes, the holes located on the specific position may have a shape different from the shape of the other holes, e.g., may be square-shaped holes other than the shape of circular holes.

### Second Embodiment

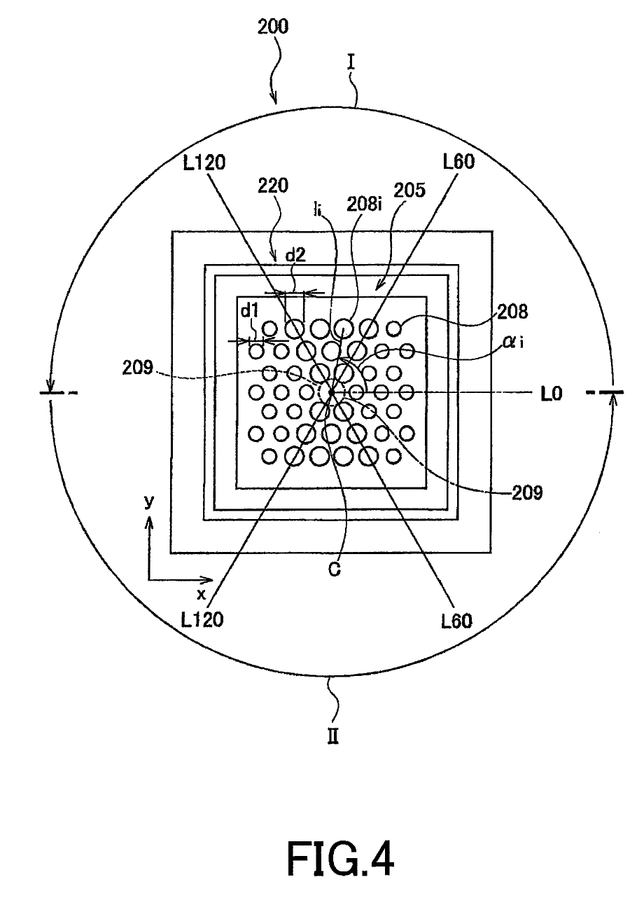

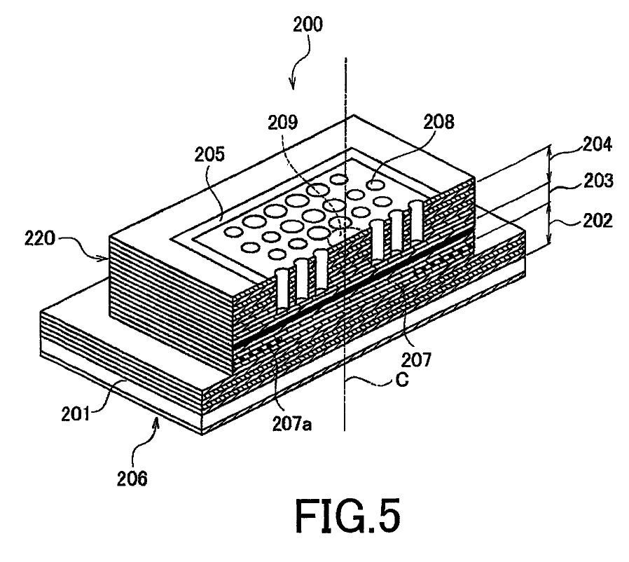

FIG. 4 is a top plan view of a VCSEL according to a second embodiment of the present invention, and FIG. 5 is a sectional perspective view thereof.

The VCSEL 200 according to the second embodiment of the present invention is a photonic-crystal VCSEL for use in a lasing wavelength of 1300 nm, wherein the lower reflector 202 is deposited by MOCVD (metal-organic-chemical vapor deposition) technique on the (100) surface of an n-type GaAs substrate 201, thereafter a lower cladding layer made of GaAs, a multiple-quantum well layer made of four pairs of GaInNAsSb/GaNAs, and an upper cladding layer made of GaAs are consecutively deposited to configure an active layer 203 by using MBE (molecular beam epitaxy) technique, and thereafter an upper reflector 204 is deposited using MOCVD technique, thereby configuring the overall layer structure.

The lower reflector 202 includes a semiconductor multilayer film configured by 35 pairs of alternately deposited n-type AlAs and n-type GaAs layers, each of the layers having a thickness of λ/4n (where n is a refractive index and λ is an operating wavelength). The upper reflector 204 includes a semiconductor multilayer film configured by 22 pairs of alternately deposited p-type Al_{0.9}Ga_{0.1}As and p-type GaAs, each of the layers having a thickness of λ/4n.

A portion of the above layer structure as viewed from the top thereof to at least the top surface of the lower reflector 202 is removed by etching for the peripheral part thereof, to configure a columnar layer structure 220. A ring-shaped upper electrode 205 made of Au/AuZn is formed on the top surface of the columnar layer structure 220, and a lower electrode 206 made of Ti/Pt/Au is formed on the bottom surface of the n-type GaAs substrate 201.

The current confinement structure in the VCSEL of the second embodiment is configured by forming a photoresist mask (not shown) by using a photolithographic technique, and implanting a suitable amount of hydrogen ions at an acceleration voltage such that a mean injection range is in the vicinity of the bottom of the upper reflector 204, to thereby transform the same into a high-resistance area 207a.

After forming the current confinement structure, as shown in FIG. 4, a plurality of circular holes 208 are formed and arranged in the columnar structure 220, to form a two-dimensional triangular-lattice structure within the layer plane, by using an electron beam exposure or photolithography and a dry etching. This circular-hole arrangement includes a point defect area 209 in the central area thereof, the point defect area including therein no circular hole. The plurality of circular holes 208 has an arrangement period of 5 micrometers (in the distance between centers thereof), and are formed to the depth corresponding to 15 pairs of the upper reflector 204 from the top surface of the columnar layer structure 220. Due to such a circular-hole arrangement, the average refractive index of the portion in which the circular holes 208 are formed is lower than the average refractive index of the point defect area 209 without a circular hole, whereby the portion in which the circular holes 208 are formed functions as a clad to the light propagating in the point defect area 209. The arrangement period, hole diameter, depth etc. of the circular holes 208 are adjusted as desired so that the fundamental transverse mode lasing may be obtained within the layer plane depending on the average refractive index difference between the portion in which the circular holes 208 are formed and the point defect area 109 without a circular hole.

In the second embodiment, the diameter of the circular holes, the angle defined between the line segment connecting together a center of which and the center of the point defect area and a half straight line extending from the center of the point defect area within the layer plane resides within a specific range, is made different from the diameter of the other circular holes. More specifically, as shown in FIG. 4, circular holes 208i, for which the angle αᵢ defined between the line segment li connecting together the center of the circular holes 208 and the center of the point defect area 209 and a half line L0 extending from the center of the point defect area 209 parallel to the x-axis direction within the layer plane is between 60 degrees and 120 degrees, inclusive of both angles, have a diameter larger than that of the circular holes disposed within a range below 60 degrees or above 120 degrees. In the example shown in FIG. 4, the diameter d₂ of circular holes having a center disposed between a half line L60 which defines an angle of 60 degrees with respect to the half lines L0 and another half line L120 which defines an angle of 120 degrees with respect to the half line L0 (including circular holes having their centers on each of the above half lines) is 2.5 micrometers, and the diameter d₁ of the other circular holes is 1.5 micrometers.

In the second embodiment, the arrangement of the circular holes having such different hole diameters allows the pattern of circular holes to have a two-fold rotational symmetry with respect to the central axis C passing through the center of the point defect area 209 perpendicularly to the layer plane, as shown at numerals I and II in FIG. 4. That is, the electromagnetic field distribution of the light of the VCSEL within the half plane containing therein the central axis is equivalent to that after rotation thereof by 180 degrees around the central axis as a rotational center.

Corresponding to the symmetry of arrangement pattern of the above circular holes, the polarization modes of the VCSEL 200 include two possible polarization modes. However, the losses incurred for the two polarization modes differ from each other. In the second embodiment, the loss incurred for the polarization mode having an electric field component parallel to the x-direction shown in FIG. 4 is smaller than the loss incurred for the polarization mode parallel to the y-direction, whereby the polarization mode lasing in the x-direction becomes dominant.

Accordingly, upon injecting current through the electrodes 205, 206, only the lasing in the polarization mode in the x-direction having a lower loss occurs out of these two polarization modes. Thus, a stable lasing is generated in which switching between polarization modes due to fluctuation of the environmental temperature, drive current etc. scarcely occurs.

Calculation conducted using the above parameters with respect to the second embodiment assured occurring of a dominant polarization mode in the x-direction, and provided a ratio (orthogonal polarization suppression ratio) of 30 dB in the lasing intensity between the polarization mode in the x-direction and the polarization mode in the y-direction. It was assured here that a fundamental transverse mode lasing is obtained for the transverse mode.

In the second embodiment, the diameter of circular holes having a center located between the half line L60 which defines 60 degrees with respect to half line L0 and the half line L120 which defines 120 degrees with respect to half line L0 (including circular holes having their centers on each of the half lines) have a diameter larger than the diameter of the other circular holes. However, circular holes having a center located between the half line L0 and another half line defining an arbitrary angle with respect to the half line L0 may have a diameter different from the diameter of the other circular holes, in order to differentiate the loss between the polarization modes.

In other words, in the second embodiment, a plurality of circular holes, for which an angle αᵢ defined between the half line L0 passing through the center of the point defect area 209 and the line segment lᵢ connecting together the center of the circular holes and the center of the point defect area 209 resides within a specific range, have a diameter different from the diameter of the other circular holes. Thus, the degree of rotational asymmetry with respect to the central axis C can be further intensified, to thereby enhance the stability of the lasing polarization mode.

Although, in the above description, the circular holes located on the specific position among the plurality of circular holes have a diameter different from the diameter of the other circular holes, the holes located on the specific position may have a shape different from the shape of the other holes, e.g., the circular holes may be square-shaped holes other than the shape of circular holes.

### Third Embodiment

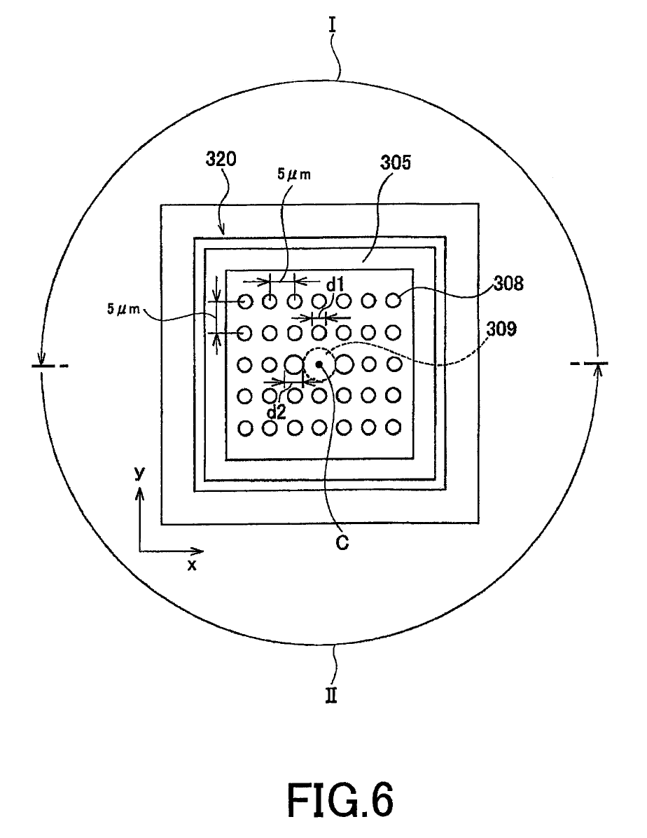

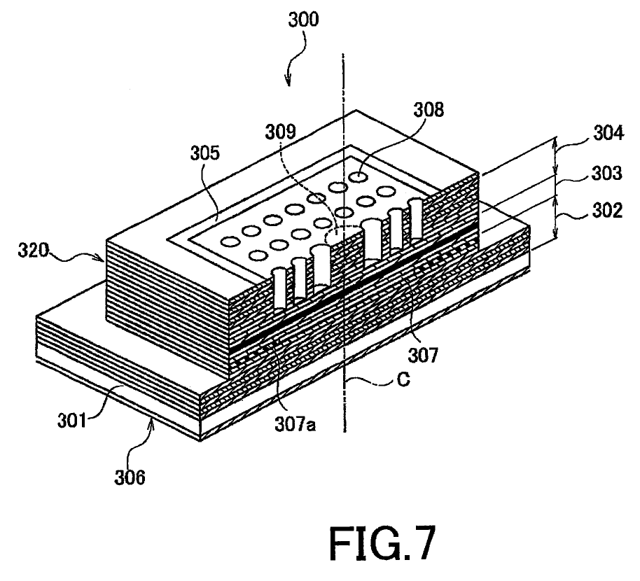

FIG. 6 is a top plan view of a VCSEL according to a third embodiment of the present invention, and FIG. 7 is a sectional perspective view thereof. The third embodiment is directed to a photonic-crystal VCSEL for use in an emission wavelength of 850 nm, similarly to the first embodiment, and the configuration and fabrication method are similar to those of the first embodiment except for the arrangement of the circular holes.

In the third embodiment, a plurality of circular holes are arranged in a square-lattice structure having a period of 5 micrometers except for the central point defect area 309. The diameter d₂ of a pair of circular holes in the vicinity of the point defect area 309 is larger than the diameter d₁ of the other circular holes. Here, d₂ is 3 micrometers and d₁ is 2 micrometers. The depth of the circular holes corresponds to the order of 17 pairs in the upper reflector 304 from the top surface of the layer structure. It should be noted that the period, diameter and depth of the circular holes are not limited to the above values so long as the light existing in the point defect area 309 is of the fundamental transverse mode.

In the third embodiment, the arrangement of circular holes having different diameters allows the arrangement pattern of the circular holes to have a two-fold rotational symmetry with respect to the central axis C passing through the center of the point defect area 309 perpendicularly to the layer plane, as shown by numerals I and II in FIG. 6. More specifically, the electromagnetic field distribution of light of the VCSEL within the half plane containing therein the central axis is equivalent to that after rotation thereof by 180 degrees around the central axis as a rotational center.

Corresponding to the symmetry of arrangement pattern of the above circular holes, the polarization modes of the VCSEL 300 include two possible polarization modes. However, the losses incurred for the two polarization modes differ from each other. In the third embodiment, the loss incurred for the polarization mode having an electric field component parallel to the x-direction shown in FIG. 4 (direction parallel to the direction connecting together the centers of larger-diameter circular holes) is larger than the loss incurred for the polarization mode parallel to the y-direction (direction perpendicular to the x-direction within the layer plane), whereby the polarization mode in the y-direction becomes dominant.

Accordingly, upon injecting current through the electrodes 205, 206, only the lasing in the polarization mode in the y-direction having a lower loss occurs out of these two polarization modes. Thus, a stable lasing is generated in which switching between polarization modes due to fluctuation of the environmental temperature, drive current etc. scarcely occurs.

Calculation also conducted using the above parameters with respect to the third embodiment assured occurring of a dominant polarization mode in the y-direction, and provided a ratio (orthogonal polarization suppression ratio) of 30 dB in the lasing intensity between the polarization mode in the x-direction and the polarization mode in the y-direction. It was assured here that a fundamental transverse mode lasing is obtained for the transverse mode.

In the third embodiment, as shown in FIG. 6, the diameter d₂ of circular holes in one of the pairs of circular holes having a smallest distance therebetween among the pairs opposing each another with an intervention of the central point defect area 109 is determined to be larger than the diameter d₁ of the others of the circular holes. This example is advantages, due to the fact that the pair of circular holes having the smallest distance with respect to the point defect area 309 have a diameter different from the diameter of the other circular holes, in that the different diameters of the circular holes provide the effect thereof more effectively to the electric field of the laser light existing in the point defect area 309. In addition, since circular holes having the same diameters are arranged with a two-dimensional uniformity in the peripheral area excepting the vicinity of the central point defect area 309, a disturbance on the distribution of refractive index within the layer plane can be reduced. In other words, the influence on the shape of the laser light can be reduced.

It should be noted however that a pair of circular holes other than the circular holes having the smallest distance with respect to the point defect area 109 may have a different diameter, in order to differentiate the loss between the polarization modes.

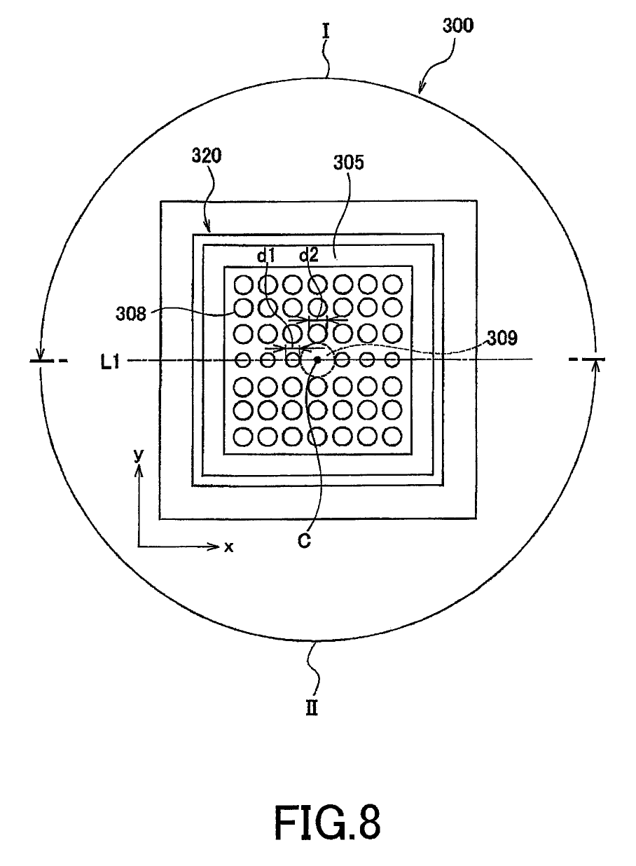

Further, as shown in FIG. 8, all the circular holes having a center arranged on a straight line, which extends through the center of the point defect area 309 and parallel to the layer plane, may have a diameter different from the diameter of the other circular holes. In the exemplified modification shown in FIG. 8, the diameter d₁ of the circular holes having a center on the straight line L1 extending through the center of point defect area 309 and parallel to the x-axis is made smaller than the diameter d₂ of the other circular holes having a center not located on the straight line L1. For this reason, the loss for the polarization mode in the x-axis direction, shown in FIG. 8, is smaller than the loss for the polarization mode in the y-axis direction. Therefore, a selective lasing occurs for the polarization mode in the x-axis direction, whereby switching between the polarization modes can be prevented. Thus, the configuration that all the circular holes having a center located on the straight line L1 passing through the center of the point defect area 109 have a diameter different from the diameter of the other circular holes having a center not located on the straight line L1 further intensifies degree of the rotational asymmetry with respect to the central axis C, thereby increasing the stability of lasing polarization mode.

Although, in the above description, the circular holes located on a specific position among the plurality of holes (circular holes) have a diameter different from the diameter of the other circular holes, the holes located on the specific position may have a shape different from the shape of the other holes, e.g., the holes may be square-shaped holes other than the shape of circular holes.

### Fourth Embodiment

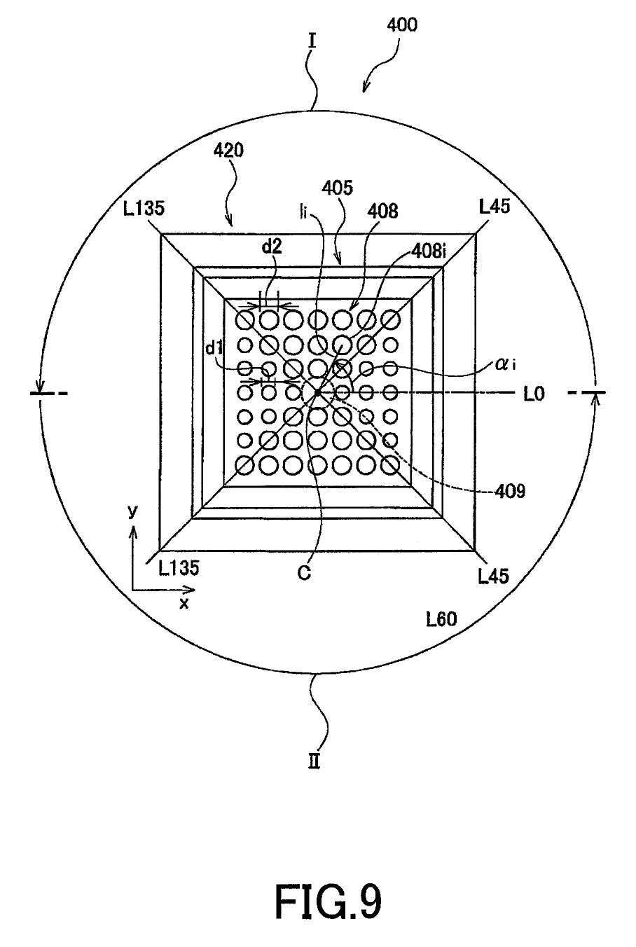

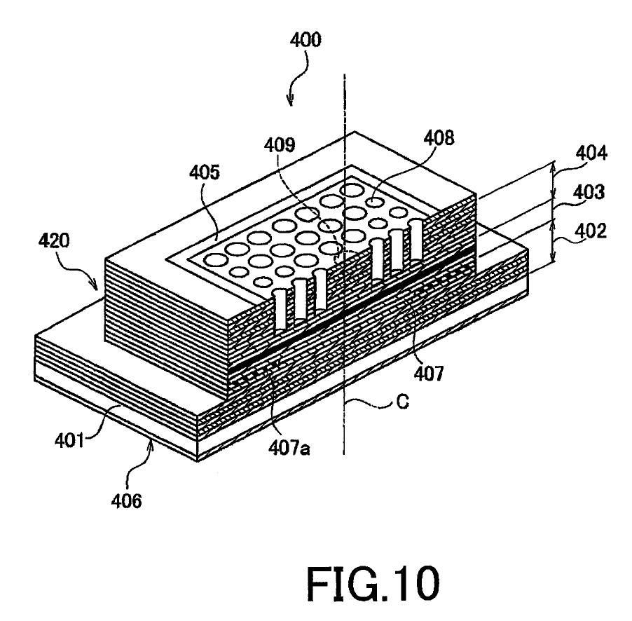

FIG. 9 is a top plan view of a VCSEL according to a fourth embodiment of the present invention, and FIG. 10 is a sectional perspective view thereof. The fourth embodiment is directed to a photonic-crystal VCSEL for use in an emission wavelength of 1300 nm, similarly to the second embodiment, and the configuration and fabrication method are similar to those of the second embodiment except for the arrangement of the circular holes.

In the fourth embodiment, as shown in FIG. 9, the diameter of the circular holes, the angle defined between a line segment connecting together the center of which and the center of the point defect area and a half straight line extending from the center of the point defect area 409 within the layer plane resides within a specific range, is made different from the diameter of the other circular holes. More specifically, as shown in FIG. 9, the circular holes, for which the angle αᵢ defined between the line segment li connecting together the center of the circular holes 408i and the center of the point defect area 409 and a half line L0 extending from the center of the point defect area 409 parallel to the x-axis direction within the layer plane resides between 45 degrees and 135 degrees, inclusive of both angles, have a diameter larger than that of the circular holes disposed within a range below 45 degrees or above 135 degrees. In the example shown in FIG. 9, the diameter d₂ of circular holes having a center disposed between a half line L45 which defines an angle of 45 degrees with respect to the half lines L0 and another half line L135 which defines an angle of 135 degrees with respect to the half line L0 (including a circular hole having a center on each of the above half lines) is 2.5 micrometers, and the diameter d₁ of the other circular holes is 1.5 micrometers.

In the fourth embodiment, the above arrangement of the circular holes having different hole diameters allows the pattern of circular holes to have a two-fold rotational symmetry with respect to the central axis C passing through the center of the point defect area 409 perpendicularly to the layer plane, as shown by numerals I and II in FIG. 9. That is, the electromagnetic field distribution of the light of the VCSEL within the half plane containing therein the central axis is equivalent to that after rotation thereof by 180 degrees around the central axis as a rotational center.

Corresponding to the symmetry of arrangement pattern of the above circular holes, the polarization modes of the VCSEL 200 include two possible polarization modes. However, the losses incurred for the two polarization modes differ from each other. In the present embodiment, the loss incurred for the polarization mode having an electric field component parallel to the x-direction shown in FIG. 9 is smaller than the loss incurred for the polarization mode parallel to the y-direction, whereby the polarization mode in the x-direction is dominant.

Accordingly, upon injecting current through the electrodes 405, 406, only the lasing in the polarization mode in the x-direction having a lower loss occurs out of these two polarization modes. Thus, a stable lasing is generated in which switching between polarization modes due to fluctuation of the environmental temperature, drive current etc. scarcely occurs.

Calculation conducted using the above parameters with respect to the fourth embodiment assured occurring of a dominant polarization mode in the x-direction, and provided a ratio (orthogonal polarization suppression ratio) of 30 dB in the lasing intensity between the polarization mode in the x-direction and the polarization mode in the y-direction. It was assured here that a fundamental transverse mode lasing is obtained for the transverse mode.

In the fourth embodiment, the diameter of circular holes having a center between the half line L45 which defines 45 degrees with respect to the half line L0 and the half line L135 which defines 135 degrees with respect to the half line L0 (including a circular hole having a center on each of the half lines) have a diameter larger than the diameter of the other circular holes. However, circular holes having a center located within an area between the half line L0 and another half line defining an arbitrary angle with respect to the half line L0 may have a diameter different from the diameter of the other circular holes, in order to differentiate the loss between the polarization modes.

In other words, in the fourth embodiment shown in FIG. 9, a plurality of circular holes, for which the angle αᵢ defined between the half line L0 passing through the center of the point defect area 409 and the line segment connecting together the center of the circular holes and the center of the point defect area 409 resides within a specific range, have a diameter different from the diameter of the other circular holes. Thus, the degree of rotational asymmetry with respect to the central axis C can be further intensified, to thereby enhance the stability of the lasing polarization mode.

Although, in the above description, the circular holes located on the specific position among the plurality of circular holes have a diameter different from the diameter of the other circular holes, the holes located on the specific position may have a shape different from the shape of the other holes, e.g., the holes may be square-shaped holes other than the shape of circular holes.

### Fifth Embodiment

In the first through fourth embodiments, the diameter of circular holes located on the specific position among the plurality of circular holes arranged in a periodical two-dimensional arrangement have a diameter different from the diameter of the other circular holes, whereby the number of possible polarization modes is two, and the loss incurred for one of the two polarization modes is smaller than the loss incurred for the other of the polarization modes.

On the other hand, in the fifth embodiment, a loss media which incurs a loss to the laser light is embedded into the circular holes specified similarly to the case of the first through fourth embodiments. In the fifth embodiment, the configuration is not necessarily employed that some of circular holes located on the specified position among the plurality of circular holes arranged in a two-dimensional arrangement have a diameter different from the diameter of the other circular holes.

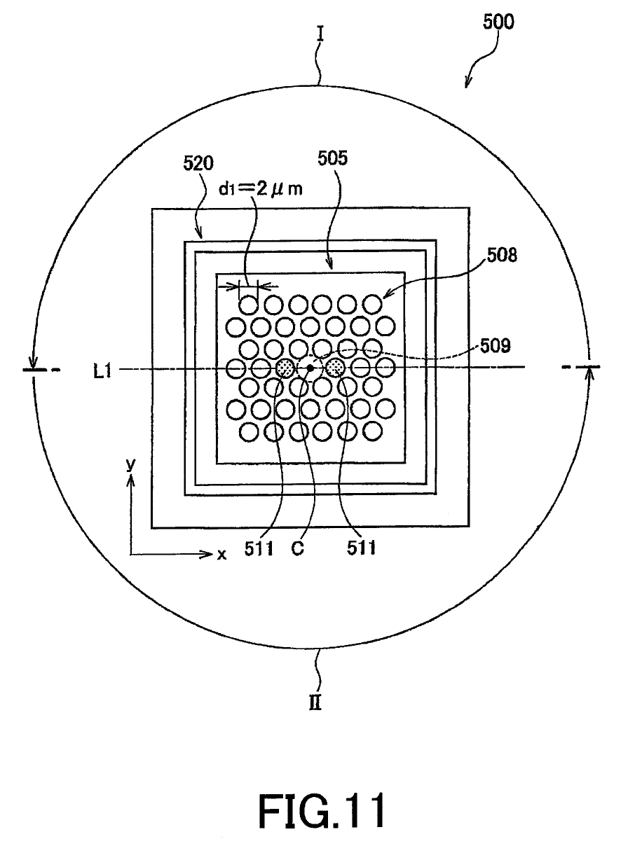

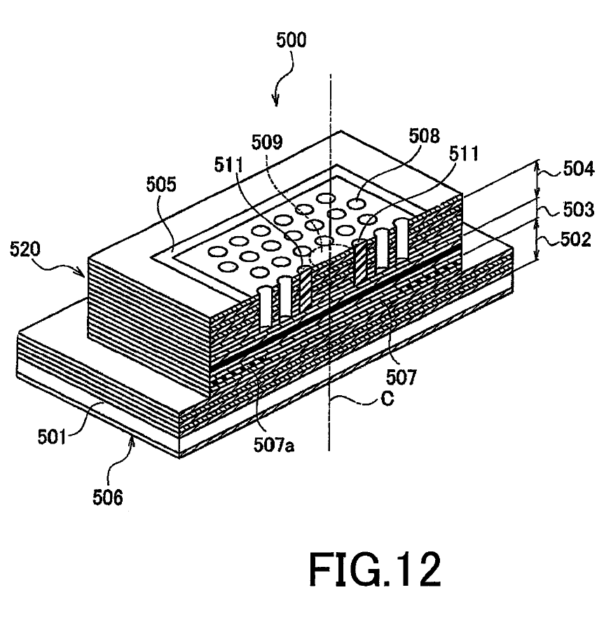

FIG. 11 is a top plan view of a VCSEL according to the fifth embodiment of the present invention, and FIG. 12 is a sectional perspective view thereof. In the fifth embodiment, the diameter d₁ of all the circular holes arranged in the periodic two-dimensional arrangement outside the central point defect area 509 is 2 micrometers, and only the internal of circular holes in a pair opposing each other with an intervention of the point defect area 509 is filled with polyimide 511 as a loss medium against the emitted laser light. This allows the loss incurred for the polarization mode in the x-direction to be larger than the loss incurred for the polarization mode in the y-direction. Thus, upon injecting current via the electrodes 506, 507, a selective lasing occurs in the polarization mode in the y-direction having a relatively smaller loss. Accordingly, a stable lasing in which switching between polarization modes due to fluctuation of the environmental temperature, drive current etc. scarcely occurs.

Although the fifth embodiment is such that the internal of circular holes in a pair sandwiching therebetween the point defect area to oppose each other is filled with the loss medium, the fifth embodiment is not limited thereto. In an exemplified modification of the fifth embodiment, the internal of circular holes having a center on a straight line passing through the center of the point defect area within the layer plane may be filled with the loss medium.

In another exemplified modification, the internal of circular holes, for which an angle defined between a half straight line extending from the center of the point defect area within the layer plane and a line segment connecting together the center of the circular holes and the center of the point defect area resides within a specific range, may be filled with the loss medium. For example, in the case of a triangular-lattice arrangement for the plurality of circular holes, the internal of circular holes, for which the angle defined between a half line extending from the center of the point defect area within the layer plane and the line segment connecting together the center of the circular holes and the center of the point defect area resides in the range between 60 degrees and 120 degrees, inclusive of both angles, may be filled with the loss medium. In the case of a square-lattice arrangement for the plurality of circular holes, the internal of circular holes, for which the angle defined between a half line extending from the center of the point defect area within the layer plane and the line segment connecting together the center of the circular holes and the center of the point defect area resides in the range between 45 degrees and 135 degrees, inclusive of both angles, may be filled with the loss medium.

In either of the above cases, a selective lasing in one of the polarization modes occurs out of a plurality of possible polarization modes defined by the rotational symmetry of the arrangement pattern of the circular holes with respect to the central axis C extending through the center of the point defect area perpendicularly to the layer plane. As a result, a stable lasing is achieved in which switching between polarization modes due to the fluctuation of environmental temperature, drive current etc. scarcely occurs.

In addition to the configuration in the fifth embodiment wherein the circular holes located on the specific position are filled with the loss medium, an additional configuration may be employed wherein the diameter of the circular holes located on the specific position is made different from the diameter of the other circular holes, as described with respect to the first through fourth embodiments.

### Sixth Embodiment

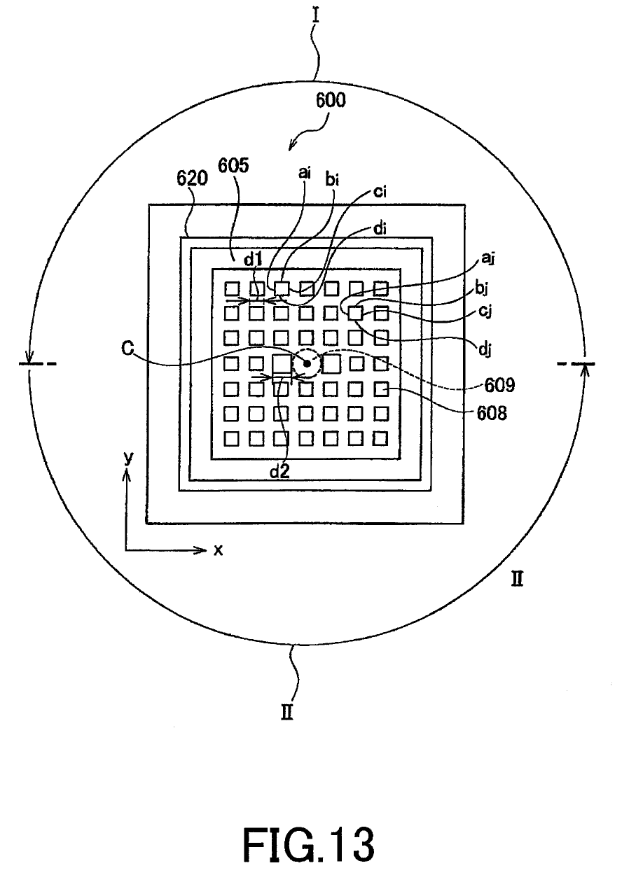

FIG. 13 is a top plan view of a VCSEL according to a sixth embodiment of the present invention. In the first through fifth embodiments, the plurality of holes are configured by circular holes. On the other hand, in the sixth embodiment, a plurality of square holes are arranged in a square lattice arrangement in the directions of x-axis and y-axis, as shown in FIG. 13. In the present embodiment, each side of the square holes are parallel to the x-axis or y-axis. Two sides (aᵢ, cᵢ,) and (bᵢ, dᵢ) of an arbitrary square hole 608i are arranged to be parallel to the corresponding two sides (aⱼ, cⱼ) and (bⱼ, dⱼ), respectively, of another square hole 608j. In addition, the dimension of a pair of holes sandwiching therebetween the point defect area 609 to oppose each other is made larger than the dimension of other holes.

In the sixth embodiment, as shown in FIG. 13, the dimension d₂ (length of a side of the square) of a pair of holes disposed in the vicinity of the center and sandwiching therebetween the point defect area 609 to oppose each other is larger than the dimension d₁ of the other holes. In the present embodiment, the dimensions d₁ and d₂ of the holes are 2 micrometers and 3 micrometers, respectively, for example. The arrangement of such square holes having different dimensions allows the arrangement pattern of the holes to have a two-fold rotational symmetry with respect to the central axis C passing through the center of the point defect area 609 perpendicularly to the layer plane, as shown by numeral I and II in FIG. 13 (that is, the electromagnetic field distribution of the light of the VCSEL within the half plane containing the central axis is equivalent to that after rotation thereof by 180 degrees around the central axis as a rotational center).

Corresponding to the symmetry of arrangement pattern of the above holes, the polarization modes of the VCSEL 600 include two possible polarization modes. However, the losses incurred for the two polarization modes differ from each other. In the present embodiment, the loss incurred for the polarization mode having an electric field component parallel to the x-direction shown in FIG. 13 is larger than the loss incurred for the polarization mode parallel to the y-direction, whereby the polarization mode in the y-direction is dominant.

Accordingly, upon injecting current through the upper electrode 605 and lower electrode (not shown), only the lasing in the polarization mode in the y-direction having a lower loss occurs out of these two polarization modes. Thus, a stable lasing is generated in which switching between polarization modes due to fluctuation of the environmental temperature, drive current etc. scarcely occurs.

In the sixth embodiment, the dimension of holes in a pair sandwiching therebetween the point defect area 609 to oppose each other is made larger than the dimension of the other holes, as in the configuration of the first embodiment. However, the dimension of the holes having a center on the specific position may be made different from the dimension of the other holes, as in the configuration of each of the second through fourth embodiments.

Instead of employing a different dimension for the holes located on the specific position, a different shape of the holes may be employed, and in addition to this configuration, the holes located on the specific position may be filled with a loss medium such as polyimide that incurs a loss to the laser light, similarly to the fifth embodiment.

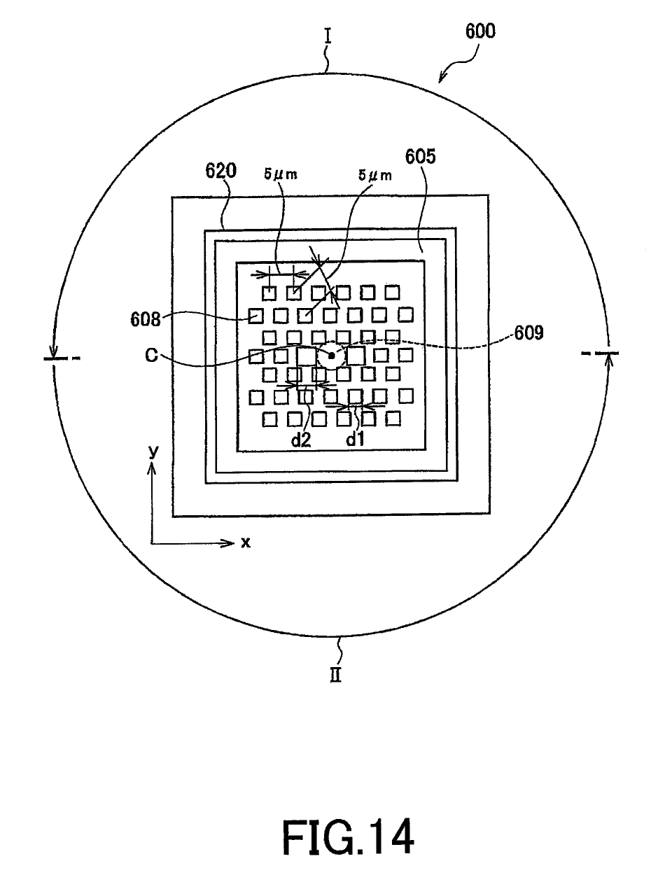

Although, the square holes are arranged in a square-lattice arrangement in the directions of x-axis and y-axis in the sixth embodiment, the square holes may arranged in a equilateral-triangular-lattice arrangement in the directions of x-axis and y-axis as shown in FIG. 14, wherein each side of the square holes may be parallel to the x-axis or y-axis.

Although the present invention is described based on the preferred embodiments thereof, the VCSEL of the present invention is not limited to the above embodiments, and a variety of alterations and modifications made from the configurations of the above embodiments will fall within the scope of the present invention.

1. A surface-emitting laser (VCSEL) comprising:
a substrate;
a layer structure including a first reflector, an active layer, and a second reflector which are consecutively layered on said substrate; and
a plurality of holes extending in a layered direction and arranged in a periodic two-dimensional arrangement within a layer plane of said layer structure except for a specific area in said layer plane,
wherein a pair of holes sandwiching therebetween said specific area to oppose each other have a dimension or shape different from a dimension or shape of others of said holes.

2. A surface-emitting vertical-cavity laser (VCSEL) comprising:
a substrate;
a layer structure including a first reflector, an active layer, and a second reflector which are consecutively layered on said substrate; and
a plurality of holes extending in a layered direction and arranged in a periodic two-dimensional arrangement within a layer plane of said layer structure except for a specific area in said layer plane;
wherein some of said holes having a center located on a straight line passing through a center of said specific area within said layer plane have a dimension or shape different from a dimension or shape of others of said holes.

3. A surface-emitting vertical-cavity laser (VCSEL) comprising:
a substrate;
a layer structure including a first reflector, an active layer, and a second reflector which are consecutively layered on said substrate; and
a plurality of holes extending in a layered direction and arranged in a periodic two-dimensional arrangement within a layer plane of said layer structure except for a specific area in said layer plane,
wherein some of said holes, the angle defined between a line segment connecting together a center of which and a center of said specific area and a half straight line extending from said center of said specific area within said layer plane resides within a specific range, have a dimension or shape different from a dimension or shape of others of said holes.

4. The VCSEL according to claim 3, wherein said plurality of holes are arranged in a triangular-lattice structure within said layer plane, and said some of said holes are such that said angle resides within a range between 60 degrees and 120 degrees, inclusive of both angles.

5. The VCSEL according to claim 3, wherein said plurality of holes are arranged in a square-lattice structure within said layer plane, and said some of said holes are such that said angle resides within a range between 45 degrees and 135 degrees, inclusive of both angles.

6. A surface-emitting vertical-cavity laser (VCSEL) comprising:
a substrate;
a layer structure including a first reflector, an active layer, and a second reflector which are consecutively layered on said substrate; and
a plurality of holes extending in a layered direction and arranged in a periodic two-dimensional arrangement within a layer plane of said layer structure except for a specific area in said layer plane,
wherein a pair of holes among said holes, which sandwich therebetween said specific area to oppose each other, are filled with a loss medium that incurs a loss to a laser light.

7. A surface-emitting vertical-cavity laser (VCSEL) comprising:
a substrate;
a layer structure including a first reflector, an active layer, and a second reflector which are consecutively layered on said substrate; and
a plurality of holes extending in a layered direction and arranged in a periodic two-dimensional arrangement within a layer plane of said layer structure except for a specific area in said layer plane,
wherein some of said holes having a center located on a straight line passing through a center of said specific area within said layer plane are filled with a loss medium that incurs a loss to a laser light.

8. A surface-emitting vertical-cavity laser (VCSEL) comprising:
a substrate;
a layer structure including a first reflector, an active layer, and a second reflector which are consecutively layered on said substrate; and
a plurality of holes extending in a layered direction and arranged periodically in a two-dimensional arrangement within a layer plane of said layer structure except for a specific area in said layer plane,
wherein some of said holes, the angle defined between a line segment connecting together a center of which and a center of said specific area and a half straight line extending from said center of said specific area within said layer plane resides within a specific range, are filled with a loss medium that incurs a loss to a laser light.

9. The VCSEL according to claim 8, wherein said plurality of holes are arranged in a triangular-lattice structure within said layer plane, and said some of said holes are such that said angle resides within a range between 60 degrees and 120 degrees, inclusive of both angles.

10. The VCSEL according to claim 8, wherein said plurality of holes are arranged in a square-lattice structure within said layer plane, and said some of said holes are such that said angle resides within a range between 45 degrees and 135 degrees, inclusive of both angles.

11. The VCSEL according to any one of claims 6 to 10, wherein said loss medium includes polyimide.

12. The VCSEL according to any one of claims 1 to 10, wherein said plurality of holes are circular holes.

13. The VCSEL according to any one of claims 1 to 10, wherein said plurality of holes are square holes, one of which has two opposing sides parallel to two opposing sides of another of said holes.

14. A surface-emitting vertical-cavity laser (VCSEL) comprising:
a substrate;
a layer structure including a first reflector, an active layer, and a second reflector which are consecutively layered on said substrate; and
a plurality of holes extending in a layered direction and arranged in a periodic two-dimensional arrangement within a layer plane of said layer structure except for a specific area in said layer plane,
wherein a rotational symmetry of an arrangement pattern of said holes with respect to a central axis configured by an axis passing through a center of said specific area in said layered direction defines a plurality of possible polarization modes, one of which has a loss smaller than a loss of another of said polarization modes.
